(19) United States
(12) Patent Application Publication
(10) Pub. No.: US 2011/0254562 A1
(43) Pub. Date: Oct. 20, 2011

(54) METHOD AND DEVICE FOR DETECTING SHORT-CIRCUITS IN THE STATOR CORE OF ELECTRIC MACHINES

(75) Inventors: Max Hobelsberger, Wuerenlingen (CH); Zlatimir Posedel, Neuenhof (CH)

(73) Assignee: ALSTOM TECHNOLOGY LTD, Baden (CH)

(21) Appl. No.: 13/081,658

(22) Filed: Apr. 7, 2011

Related U.S. Application Data
(63) Continuation of application No. PCT/EP2009/063009, filed on Oct. 7, 2009.

(30) Foreign Application Priority Data
Oct. 8, 2008 (CH) 01601/08

(51) Int. Cl. G01R 31/34

(52) U.S. Cl. 324/521; 324/765.01

(57) ABSTRACT

A method for detecting turn-to turn faults in a laminate stack of a stator of an electrical machine or a generator includes magnetizing the stator using an auxiliary coil and an auxiliary current so as to form a magnetic field. The magnetic field is measured using a pickup device including at least two detectors disposed in at least two respective different radial positions with respect to a rotor axis so as to provide at least two signals corresponding to the magnetic field at the respective radial positions. The method includes evaluating and comparing a magnitude and/or a phase angle of the signals so as to determine a relative magnitude and/or relative phase angle by subtraction in order to detect turn-to-turn faults. Relative differences in the at least two signals are recorded. Also a device for performing the method.

### CROSS REFERENCE TO RELATED APPLICATIONS

This application claims priority to International Patent Application No. PCT/EP2009/063009 filed Oct. 7, 2009, which claims priority to Swiss Patent Application No. CH 01601/08, filed Oct. 8, 2008, both of which are incorporated by reference herein in their entirety.

### FIELD

The present invention relates to a device and a method for detecting turn-to-turn faults in the laminate stack of a stator of an electrical machine or a generator.

### BACKGROUND

Large generators and motors are routinely investigated in the standstill state for interlamination faults. Various methods are available for this purpose.

One of these methods comprises magnetizing the entire laminated core by means of an auxiliary coil at mains frequency and measuring leakage fields on the inner surface of the stator bore. The magnetization is performed to relatively low values of magnetic induction, typically to approximately 10% of the normal working inductance. This measurement method is also known under the name “low-induction interlamination fault measurement”, also referred to as “ELCID”. Such a device is described in U.S. Pat. No. 4,996,486, for example. The present invention relates to an improvement to this low-induction measurement method. A similar device is described in WO03/036287, in which phase information and amplitude information are evaluated in combined form.

Thus, there are systems that magnetize the stator laminate stack by means of an auxiliary coil and an auxiliary current at mains frequency to approximately one tenth of the working inductance.

An electrical pickup coil is then passed along the surface of the stator bore, with the pickup coil being located close to the surface of the laminate stack.

The currents which are associated with interlamination short circuits of the laminated stack now induce voltages with characteristic phase and amplitude angle in the pickup coil. Owing to these characteristic phase and amplitude angles, it is possible for locations with interlamination fault currents to be distinguished from locations without any interlamination fault currents. It is thus possible to localize interlamination faults by means of this leakage field pickup coil and to assess the magnitude of the short-circuit currents.

One disadvantage with this method is the fact that it is sometimes difficult to interpret the measurement results since the voltages induced by the laminated fault currents are usually very low. In particular, strong leakage fields of the stator main field or else additional fields which are subject to losses and which may arise, for example, as a result of currents induced in the short-circuited conductor loops, can conceal the effect of the actual short-circuit current through the fault location and thus make detection more difficult. This is particularly the case in the case of small interlamination faults which only result in low currents and only have a low magnetic effect. Disruptive additional fields occur in particular when testing hydraulic generators if the rotor has not been removed for the testing, with the result that the individual poles exert a magnetic effect.

### SUMMARY

In an embodiment, the present invention provides a method for detecting turn-to turn faults in a laminate stack of a stator of an electrical machine or a generator. The method includes magnetizing the stator using an auxiliary coil and an auxiliary current so as to form a magnetic field. The magnetic field is measured using a pickup device including at least two detectors disposed in at least two respective different radial positions with respect to a rotor axis so as to provide at least two signals corresponding to the magnetic field at the respective radial positions. The method includes evaluating and comparing a magnitude and/or a phase angle of the signals so as to determine a relative magnitude and/or relative phase angle by subtraction in order to detect turn-to-turn faults. Relative differences in the at least two signals are recorded. In another embodiment, the invention provides a device for performing such a method.

### BRIEF DESCRIPTION OF THE DRAWINGS

The invention will be explained in more detail below with reference to exemplary embodiments in connection with the drawings, in which:

FIG. 1 shows a longitudinal section through a laminate stack, i.e. a section axially with respect to the rotor axis;

FIG. 2 shows a cross section through a stator laminate stack, i.e. a section in a plane perpendicular to the rotor axis;

FIG. 3 shows a phasor diagram of the measurement voltage induced in the detector coils for different situations;

FIG. 4 shows a differential field sensor;

FIG. 5 shows a differential field sensor with a common-mode trimming potentiometer;

FIG. 6 shows a differential field sensor with three detector coils; and

FIG. 7 shows a differential field sensor for measuring the differential signal and the coil individual signal.

### DETAILED DESCRIPTION

In an embodiment, the present invention provides a device and a method for detecting turn-to-turn faults in the laminate stack of a stator of an electrical machine or a generator. The stator can be magnetized for the measurement by means of an auxiliary coil and an auxiliary current and the magnetic field is measured by a pickup device. Thus, such an embodiment of the invention relates to a method and a device for detecting interlamination short circuits in the laminate stack of the stator of electrical machines, in particular of large generators.

In an embodiment, an aspect of the invention is to provide a device or a method for detecting turn-to-turn faults in the laminate stack of a stator of an electrical machine or a generator, wherein the stator is magnetized by means of an auxiliary coil and an auxiliary current and the magnetic field is measured by a pickup device. In this case, the pickup device comprises at least two detectors, which are arranged in two different radial positions with respect to the rotor axis, and at the same time measure the magnetic field in these two different radial positions, the two signals measured at these different locations being evaluated and compared with one another in terms of magnitude and/or phase angle for detecting turn-to-turn faults.

Thus, in embodiments of the invention, the relative magnitude and/or the relative phase angle of the at least two signals is determined via subtraction, and only relative differences in the signals are recorded.

Accordingly, an absolute measurement can be dispensed with by virtue of the subtraction of the two different signals to a certain extent and only recording relative differences in the signals. The two detectors, normally coils, are in this case generally not isolated from one another electrically in a very targeted manner. Thus, disruptive additional fields can be blocked out to a certain extent and the diagnosis is thus substantially simplified. In contrast to other systems, which are only concerned with performing radial localization of short circuits by virtue of the proposed device (i.e. it is already known where there is a short circuit, with this having been determined by another method, and then the extent of this short circuit is determined), the proposed method or the proposed device makes it possible to use the method for identifying short circuits (i.e. for answering the question as to whether there are short circuits at all) and not only for determining, in a second step, the radial position of a short circuit when one has already been identified and localized. Since the conventional method does not perform direct subtraction and correspondingly does not allow any compensation, it is not suitable for large-area identification/localization of short circuits, but only for determining the extent of the fault in the laminate stack at a faulty point when said faulty point has already been identified. In particular in the sector of hydraulic generators where large magnetic leakage fields are present, the conventional methods i only make it possible with difficulty to determine the extent of faults and in no way to identify/localize the fault points, but this is easily possible with a method in accordance with an embodiment of the invention. In particular when a large number of sensors are arranged in miniaturized form in combination with preamplifiers/operational amplifiers directly in the sensor head. Preferably, in this case the at least two detectors are arranged one above the other substantially in the radial direction with respect to the rotor axis. Furthermore, the detectors are electrical coils which are aligned such that they primarily measure that field component of the magnetic field which is tangential to the cylindrical inner surface of the stator bore, perpendicular to the direction of the rotor axis. In other words, the design is preferably one similar to that described in U.S. Pat. No. 4,996,486, which is hereby incorporated by reference herein in its entirety. When implementing such a method, the pickup device and/or the auxiliary coil is preferably guided substantially directly along the cylindrical inner surface of the stator bore in an axial and/or circumferential manner, and it is concluded from a sudden change in the two signals measured at the various locations in terms of relative magnitude and/or relative phase angle that there is a turn-to-turn fault, with it being possible for corresponding evaluation to be performed graphically and/or in automated fashion. Preferably, the two detectors have an identical design and are positioned in particular preferably directly one above the other.

In accordance with an embodiment of the method, the signal from one of the detectors is used as a reference signal for the subtraction.

In addition, it has proven to be advantageous if, for evaluation or analysis purposes, a representation of the coil voltages in a polar coordinate graph in terms of absolute value and phase difference is used, with preferably a large number of measurement points being illustrated or analyzed.

The subtraction can be performed in a particularly efficient manner if the relative magnitude and/or the relative phase angle of the at least two signals is determined directly in the pickup device by subtraction. In design terms, this is possible in a particularly reliable manner if, as preferred, the at least two detectors in the form of preferably identical coils are connected in series with one another, in opposition. In principle, it is possible to pass the tapped-off differential voltage first out of the electrical machine and to pass it, for example, directly via an ADC and then to evaluate it in a measurement computer. Since, however, the differential voltage or the differential phase is typically a very small signal, it has proven to be advantageous to at least perform a first preamplication directly in the pickup device. It has thus proven advantageous if the differential voltage generated by the series circuit is amplified by an amplifier arranged in the pickup device.

A further preferred embodiment of the method according to the invention is characterized by the fact that the voltage of the two coils connected in series in the same direction is tapped off via a trimming resistor, which can preferably be adjusted electronically, and is supplied to an amplifier. It is thus possible to adjust the subtraction in optimum fashion, i.e. to avoid a possible DC offset as far as possible.

It is of course possible to arrange more than only two detectors one above the other in order to enable more precise dimensioning of the gradient of the magnetic field in radial directions. Since precisely this gradient is decisive for the determination of turn-to-turn faults, it is correspondingly possibly preferred to arrange at least three detectors one above the other, for example, with preferably each of this plurality of detectors being connected to one another in series in opposition so as to form a pair. It is likewise possible to evaluate not only a subtraction but in addition also the signal of only one detector, in which case combined analysis of the difference and of the signal from one detector can possibly be performed.

Furthermore, embodiments of the present invention relate to a device for implementing a method as described above. With particular preference, the device is characterized by the fact that a pickup device with at least two detectors is arranged, wherein the detectors are arranged in two different radial positions with respect to the rotor axis and at the same time measure the magnetic field in these two different radial positions with respect to the rotor axis, and in that there is an evaluation unit which evaluates the two signals measured at these different locations in terms of magnitude and/or phase angle and/or compares said signals with one another for detecting turn-to-turn faults, wherein the relative magnitude and/or the relative phase angle of the at least two signals is determined via subtraction.

In accordance with one embodiment, the device is characterized by the fact that the at least two detectors are arranged one above the other substantially in the radial direction with respect to the rotor axis. Furthermore, it is preferably possible for the at least two detectors in the form of preferably identical coils to be connected in series with one another in the same direction, and the relative magnitude and/or the relative phase angle of the at least two signals to be determined directly in the pickup device via subtraction, with preferably an amplifier being arranged in the pickup device, said amplifier amplifying the differential voltage generated by the series circuit. In addition, a preferably electronically adjustable trimming resistor can be arranged in the pickup device, with the voltage of the two coils, which are connected in series in the same direction, being tapped of via said trimming resistor and supplied to an amplifier.

Embodiments of the present invention include an element which consists of at least two magnetically sensitive detectors S1, S2, which are arranged close one on top of the other, measured in the perpendicular direction with respect to the laminate stack surface, or close one above the other in the radial direction of the stator bore 2, that is used as detector for detecting turn-to-turn faults. The detector is preferably two electrical coils, which are arranged one above the other and are aligned in such a way that they primarily measure the tangential field component transverse to the bore axis. Such an arrangement is known, for example, from U.S. Pat. No. 4,996,486. The signals generated by these elements S1, S2 which characterize the magnet field measured in each case thereby, are evaluated and compared with one another in terms of magnitude and phase angle.

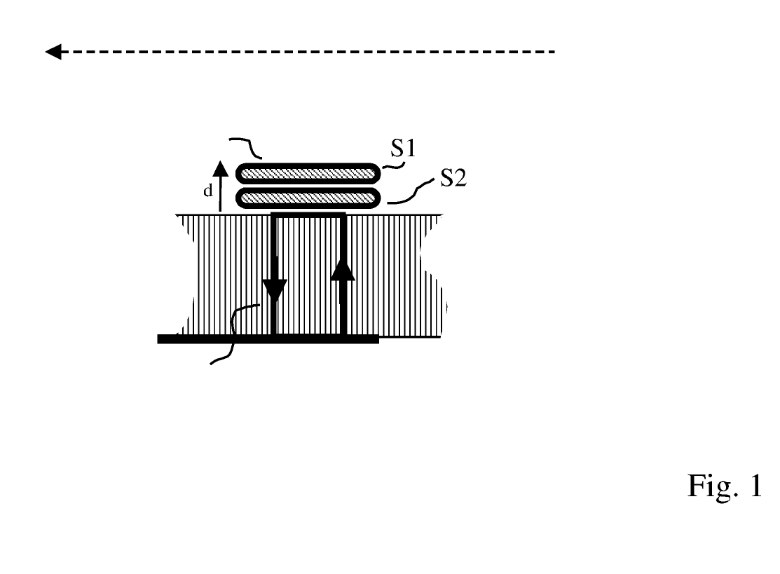

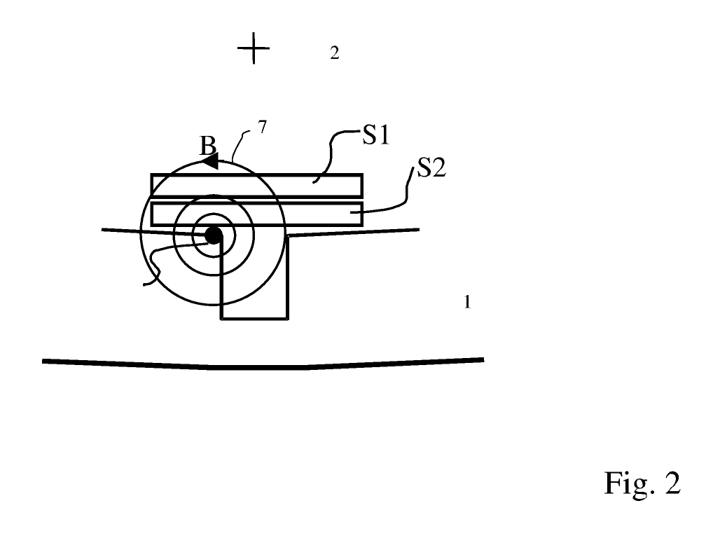

The basis for the novel method is now the knowledge that the magnetic field B generated by an interlamination short circuit (cf. FIGS. 1 and 2) is very inhomogeneous in the radial direction with respect to the rotor axis 3 and close to the stator bore surface, i.e. the axis-normal tangential component changes significantly close to the surface in the radial direction. This applies in particular to interlamination short circuits which are located directly on the surface of the stator bore, which is often the case. In contrast to this, leakage fields, for example of the stator field or fields which do not originate from a local short circuit directly on the stator surface, demonstrate a much more homogeneous distribution in the radial direction.

By comparison, it is now determined whether the signals generated by the two or more magnetically sensitive detectors S1, S2 differ from one another to a greater degree at least in terms of phase angle or whether they are approximately identical in terms of phase angle and amplitude. Relatively significant differences are interpreted as an indication of an interlamination short circuit.

The strong radial locational dependence of the magnetic inductance is thus used for identifying interlamination short circuits.

An advantageous effect of this method is the fact that, by suitably dimensioning the individual magnetically sensitive detectors or by virtue of suitable signal conditioning, the effect of homogeneous magnetic fields can be approximately suppressed.

For illustrative purposes, the general situation is illustrated using an example as in FIGS. 1-3. FIG. 1 shows a stator 1 and its bore 2 in a central axial section. FIG. 1 shows two detector coils S1 and S2 positioned one above the other in cross section and the laminate stack 5 in longitudinal section (along the rotor axis 3); the lamination plane is normal to the plane of the figures. FIG. 2 shows the same arrangement, but as a section transverse to the rotor axis. A short-circuit current 6 is indicated schematically. The pickup device, consisting of the two detector coils S1 and S2, is therefore arranged directly above the surface of the laminate stack 5. The short-circuit current 6 induces a magnetic field 7, which is indicated schematically by the circular arrows in FIG. 2 and is denoted by the reference symbol B. It can be seen from this that the intensity of the magnetic field or the magnetic flux has a strong dependence on the distance d between the respective detector and the surface of the stator bore 2.

It is therefore clear from FIG. 2
that the two coils S1 and S2, when measured in the normal direction with respect to the laminate stack bore surface, are arranged close one above the other,
that the magnetic field 7 induced by the current 6 by the interlamination short circuit has a strong radial dependence, i.e. the magnitude of the magnetic inductance of this field 7 is strongly dependent on the distance from the bore surface if the short circuit is located at the surface.

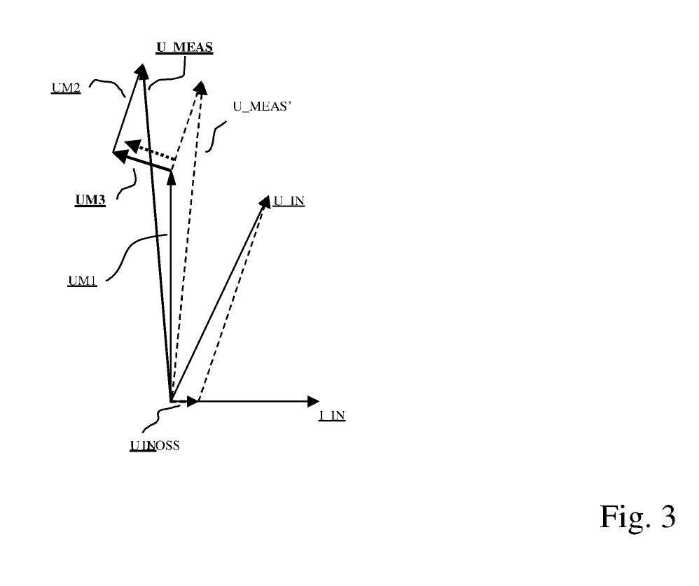

FIG. 3 shows a phasor diagram of the currents and voltages. FIG. 3 shows in particular the phasor distribution of the measurement voltage U_MEAS induced in the detector coils. This voltage can be split into three main components: one component is induced directly by the field current (UM1, field current voltage), another (UM2, core leakage voltage) is produced by the leakage field of the stator main field, and the third component (UM3, fault-current voltage) is induced by the short-circuit current 6.

Of these components, UM3 has a particularly strong dependence on the distance from the lamination surface, and the two other components are less dependent on the radial height position of the coils. It can be stated with good approximation that, given the same geometry of the two coils S1 and S2 (number of turns, cross section), UM3, the voltage produced by the short-circuit current, will primarily be different.

In other words, this means that the two measurement voltages or the phasors thereof will be approximately the same if there is no interlamination short circuit beneath the coils. If the coils are positioned over a fault point, the two phasors will differ primarily in the component UM3.

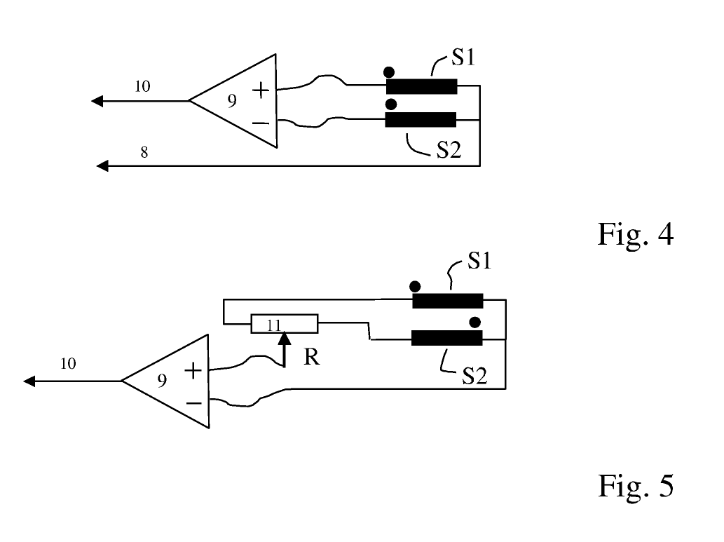

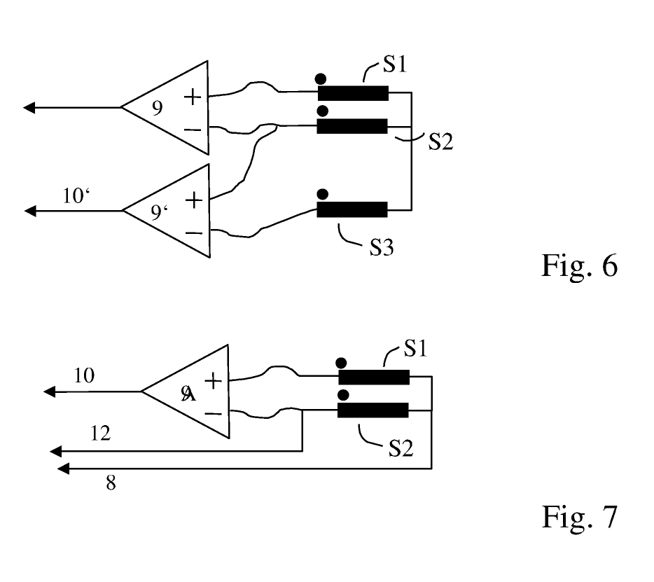

This knowledge opens up the possibility for the following evaluation methods or devices used for this purpose:
measurement and evaluation of the phase angle between the measurement voltages of the two coils:
A more pronounced, locally increased phase difference between the two signals indicates an interlamination short circuit. Typically, the measurement signal of one coil is used as the reference signal for this measurement. The phase discrepancies between the other signal and this reference signal are recorded, with the two coils being moved in the axial direction along the stator bore. Any phase angle offset can easily be identified as such at points without any faults and therefore also be corrected.
representation of one coil voltage in a polar coordinate graph in terms of absolute value and phase difference with respect to the other coil voltage, with in turn a large number of measurement points being illustrated.
calibration of the measurement device by means of a conductor loop arranged on the bore surface and a calibration current flowing through this loop.
measurement of the two coil voltages and subtraction of the values: for this purpose, the two coil voltages are measured separately, and then the two measurement values are subtracted. The resultant differential value can be recorded in terms of phase and amplitude, in turn as a function of the axial position, and be represented in a polar coordinate graph. At fault points, there is an increased phase and amplitude deflection of the differential voltage.
direct subtraction of the measurement values in the sensor: for this purpose, as shown in FIG. 4, the two identical coils S1, S2 are connected in series with one another in opposition, and therefore only differences in flux generate an output voltage. The normally very low differential voltage is amplified further by the amplifier 9 directly in the sensor. The advantage of this arrangement consists in that leakage fields influence the already amplified measurement signal to a lesser extent.
direct subtraction of the measurement values in the sensor with the possibility of compensation: for this purpose, as shown in FIG. 5, the two identical coils S1, S2 are connected to one another in series in the same direction and the voltage is tapped off via a trimming resistor 11. The device is trimmed in a homogeneous field, with the result that only differences in flux generate an output voltage. The normally very low differential voltage is further amplified by the amplifier 9 directly in the sensor. The trimming potentiometer used may be, for example, an electronically adjustable potentiometer which is adjusted, for example, by means of serial data transmission.
arrangement with a plurality of detector coils, for example three coils S1, S2, S3 as shown in FIG. 6: direct subtraction of the measurement values by serial connections in the same direction and amplification by means of two amplifiers 9 and 9′. This configuration enables even more precise determination of the field gradient.

Thus, methods and devices in accordance with embodiments of the invention provides
that, for detection of the interlamination faults, the magnetic flux differences or the changes in the tangential components of the magnetic fluxes are measured in dependence on the radial height close to the surface of the stator bore;
that increased changes in the phase angle and the amplitude of the magnetic fluxes in dependence on the radial height are evaluated as an indication of an interlamination fault,
that, in order to measure the changes in flux, two or more magnetically sensitive detectors, which primarily measure the tangential flux, are arranged one above the other in the radial direction (at a gap of typically from 1-4 mm),
that, by measuring the phase difference between two detector signals, the existence of interlamination faults is established,
that in each case two identical detectors are connected electrically in series, in opposition, with a differential signal being formed which indicates differences in flux,
that in each case two detectors are interconnected via an adjustable resistance network in such a way that the voltages induced by homogeneous magnetic fields can be reduced,
that the signal differences are formed directly at the location of the detectors and are amplified by means of amplifiers.

### LIST OF REFERENCE SYMBOLS

1 Stator
2 Stator bore
3 Direction of rotor axis
4 Cross sections through detector coils
5 Laminate stack
6 Short-circuit current
7 Magnetic field induced by short-circuit current
8 Ground (GND)
9 Amplifier
9′ Further amplifier for taking into consideration the third coil
10 Detector signal, differential signal
10′ Further detector signal with third coil, differential signal
11 Trimming resistor, potentiometer
12 Detector signal of an individual coil S2
S1 Detector, first coil
S2 Detector, second coil
S3 Detector, third coil
d Distance from the inner surface of stator bore
B Magnetic field
U_MEAS Measurement voltage with interlamination fault
U_MEAS′ Measurement voltage without interlamination fault
UM1 Field current voltage
UM2 Core leakage voltage
UM3 Fault-current voltage
I_IN Field current
U_LOSS Voltage loss, resistive cable losses
U_IN In field voltage
R Nonreactive resistance, variable

What is claimed is:

1: A method for detecting turn-to turn faults in a laminate stack of a stator of an electrical machine or a generator, the method comprising:
magnetizing the stator using an auxiliary coil and an auxiliary current so as to form a magnetic field;
measuring the magnetic field using a pickup device including at least two detectors disposed in at least two respective different radial positions with respect to a rotor axis so as to provide at least two signals corresponding to the magnetic field at the respective at least two different radial positions;
evaluating and comparing at least one of a magnitude and a phase angle of the at least two signals so as to determine at least one of a relative magnitude and relative phase angle by subtraction so as to detect turn-to-turn faults; and
recording relative differences in the at least two signals.

2: The method recited in claim 1, wherein the at least two detectors are disposed above one another substantially in a radial direction with respect to the rotor axis.

3: The method recited in claim 1, wherein each detector is an electrical coil and each detector is disposed so as to primarily measure a field component of the magnetic field that is tangential to a cylindrical inner surface of the stator bore and perpendicular to a direction of the rotor axis.

4: The method recited in claim 1, further comprising guiding at least one of the pickup device and the auxiliary coil along a cylindrical inner surface of the stator bore in at least one of an axial and circumferential manner; and
detecting a location of a turn-to-turn fault based on a sudden change in at least one the relative magnitude and relative phase angle of the at least two signals,
wherein the evaluating is performed at least one of graphically and automatically.

5: The method recited in claim 1, wherein the at least two signals is used as a reference signal.

6: The method recited in claim 1, wherein the evaluating includes representing an absolute value and phase difference of the at least two signals in a polar coordinate graph corresponding to a multiplicity of measurement points.

7: The method recited in claim 1, wherein determining at least one of a relative magnitude and relative phase angle is performed directly in the pickup device by subtraction.

8: The method recited in claim 7, wherein the at least two sensors are identical coils connected in series, in opposition.

9: The method recited in claim 7, wherein the at least two sensors are identical coils connected in series so as to generate a differential voltage, and further comprising amplifying the differential voltage in the pickup device.

10: The method recited in claim 7, wherein the at least two sensors are identical coils connected in series in a same direction, and wherein a voltage of the coils is tapped off by a trimming resistor.

11: The method recited in claim 10, wherein the trimming resistor is adjusted electronically and the voltages is supplied to an amplifier.

12: The method recited in claim 7, where the at least two sensors includes at least three sensors disposed one above the other, and connected so as to form respective pairs connected to each other in opposition.

13: The method as recited in claim 7, further comprising simultaneously evaluating a single one of the at least two signals.

14: A device for detecting turn-to turn faults in a laminate stack of a stator of an electrical machine or a generator, the device comprising:
a pickup device including at least two detectors, the at least two detectors being disposed in at least two respective radial positions with respect to a rotor axis and being configured to simultaneously measure a magnetic field at the at least two radial positions so as to generate at least two respective signals; and
an evaluation unit configured to detect turn-to-turn faults by at least one of evaluating and comparing at least one of a magnitude and a phase angle of the at least two signals so as to determine at least one of a relative magnitude and a relative phase angle of the at least two signals by subtraction.

15: The device recited in claim 14, wherein the at least two detectors are disposed above one another substantially in a radial direction with respect to the rotor axis.

16: The device recited in claim 14, wherein the at least two detectors are connected in series in a same direction, the at least one of the relative magnitude and relative phase angle of the at least two signals being determined directly in the pickup device by subtraction.

17: The device recited in claim 16, wherein the at least two detectors are identical electrical coils.

18: The device recited in claim 16, further comprising an amplifier disposed in the pickup device and being configured to amplify a differential voltage generated by series circuit of the at least two sensors.

19: The device recited in claim 14, wherein the at least two sensors are electrical coils connected in series in opposition, and further comprising an electronically adjustable trimming resistor disposed in the pickup device and configured to tap off a voltage of the series-connected coils, and an amplifier configured to receive the tapped-off voltage.
